(19) United States
(12) Patent Application Publication
(10) Pub. No.: US 2015/0224794 A1
(43) Pub. Date: Aug. 13, 2015

(54) ULTRAVIOLET RAY EMITTING DIODE UNIT, SET OF ULTRAVIOLET RAY EMITTING DIODE UNITS, INK JET DEVICE AND THREE-DIMENSIONAL MODELED OBJECT MANUFACTURING DEVICE

(71) Applicant: MIMAKI ENGINEERING CO., LTD., Nagano (JP)

(72) Inventor: MASARU OHNISHI, NAGANO (JP)

(21) Appl. No.: 14/613,371

(22) Filed: Feb. 4, 2015

(30) Foreign Application Priority Data
Feb. 7, 2014 (JP) 2014-058980

(51) Int. Cl. B41J 11/00; H01L 25/075; H01L 33/52

(52) U.S. Cl. CPC B41J 11/002; H01L 33/52; H01L 25/0753

(57) ABSTRACT

To prevent generation of stray light from an ultraviolet ray emitting diode, an ultraviolet ray emitting diode unit 10 includes a single ultraviolet ray emitting diode 4, and a single transparent member 5 arranged to include an optical axis O, and in a cross section of the transparent member 5 that includes the optical axis O and that is vertical to a first direction (X direction) that vertically intersects with the optical axis O, a width in an optical axis direction of a center portion including the optical axis O is longer than a width in the optical axis direction of a peripheral portion that is farther away from the optical axis O than the center portion.

### CROSS-REFERENCE TO RELATED APPLICATION

This application claims the priority benefit of Japan application serial no. 2014-058980, filed on Feb. 7, 2014. The entirety of the above-mentioned patent application is hereby incorporated by reference herein and made a part of specification.

### BACKGROUND OF THE INVENTION

(1) Field of the Invention

The present invention relates to an ultraviolet ray emitting diode unit, a set of ultraviolet ray emitting diode units, an ink jet device, and a three-dimensional modeled object manufacturing device.

(2) Description of Related Art

In the recent years, an ultraviolet ray emitting diode is used in various kinds of application.

For example, WO 2011/021403 A1 (published on Feb. 24, 2011) describes using ultraviolet curable ink to perform printing, and using an ultraviolet ray emitting diode as an ultraviolet ray irradiating unit in a case of curing the ultraviolet curable ink.

Patent Document 1: WO 2011/021403 A1 (published on Feb. 24, 2011)

Patent Document 2: JP 2005-205670 A (published on Aug. 4, 2005)

### SUMMARY OF THE INVENTION

That is, an ultraviolet ray emitting diode unit according to the present invention includes a single ultraviolet ray emitting diode; and a single transparent member arranged to include an optical axis of the ultraviolet ray emitting diode, wherein in a cross section of the transparent member that includes the optical axis and that is vertical to a first direction that vertically intersects with the optical axis, a width in an optical axis direction of a center portion including the optical axis is longer than a width in the optical axis direction of a peripheral portion that is farther away from the optical axis than the center portion.

According to the above configuration, in the cross section of the transparent member that includes the optical axis and that is vertical to the first direction, the width in the optical axis direction (thickness) of the center portion is made longer (thicker) than the width in the optical axis direction (thickness) of the peripheral portion. Due to this, the transparent member functions as a convex lens for an ultraviolet ray passing through the cross section, and directivity in a second direction that vertically intersects with the first direction within the cross section is improved. Accordingly, according to the above configuration, since the directivity in a specific direction can be improved, the ultraviolet ray can easily be prevented from being emitted at such an angle that causes the stray light. Thus, according to the above configuration, the stray light can be prevented from being generated from the ultraviolet ray emitting diode.

Furthermore, according to the above configuration, since the single transparent member is combined with the single ultraviolet ray emitting diode, a size of the transparent member can be made small compared to a case where a lens that entirely covers a plurality of ultraviolet ray emitting diodes is arranged on the plurality of ultraviolet ray emitting diodes that is aligned. Due to this, the deterioration in efficiency of the ultraviolet ray emitting diode unit can be avoided.

### BRIEF DESCRIPTION OF THE DRAWINGS

FIGS. 1A to 1D are schematic diagrams showing a general configuration of an ultraviolet ray emitting diode unit according to an embodiment (first embodiment) of the present invention, where FIG. 1A shows a perspective diagram, FIG. 1B shows a cross sectional diagram that is vertical to an X direction, FIG. 1C shows a cross sectional diagram that is vertical to a Y direction, and FIG. 1D shows a modification;

FIGS. 2A to 2C are schematic diagrams showing a general configuration of an ultraviolet ray emitting diode unit according to an embodiment (second embodiment) of the present invention, where FIG. 2A shows a perspective diagram, FIG. 2B shows a cross sectional diagram that is vertical to an X direction, and FIG. 2C shows a cross sectional diagram that is vertical to a Y direction;

FIGS. 3A to 3C are schematic diagrams showing a general configuration of an ultraviolet ray emitting diode unit according to a modification of the embodiment (second embodiment) of the present invention, where FIG. 3A shows a top view diagram, FIG. 3B shows a cross sectional diagram that is vertical to an X direction, and FIG. 3C shows a cross sectional diagram that is vertical to a Y direction;

FIG. 4 is a schematic diagram showing a general configuration of a set of ultraviolet ray emitting diode units according to an embodiment (fourth embodiment) of the present invention;

FIG. 5 is a schematic diagram showing a configuration of a main part of an ink jet device according to an embodiment (fifth embodiment) of the present invention;

FIGS. 6A to 6H are diagrams showing a relationship of structures of ultraviolet ray emitting diode units according to the embodiment (fifth embodiment) of the present invention and the related art and directivity of an ultraviolet ray for irradiation; and

FIGS. 7A to 7C are schematic diagrams showing a general configuration of an ultraviolet ray emitting diode unit according to an embodiment (third embodiment) of the present invention, where FIG. 7A shows a perspective diagram, FIG. 7B shows a cross sectional diagram that is vertical to an X direction, and FIG. 7C shows a cross sectional diagram that is vertical to a Y direction.

### DETAILED DESCRIPTION OF PREFERRED EMBODIMENTS

The present inventors have been examining use of an ultraviolet ray emitting diode as an ultraviolet ray irradiating unit in a laminate modeling method for manufacturing a three-dimensional modeled object by laminating print layers that are formed by printing and curing ultraviolet curable ink (JP 2005-205670 A (published on Aug. 4, 2005)). As a result, the present inventors have found that the following problems may occur.

That is, an ultraviolet ray emitting diode according to the related art is normally used by aligning a plurality of ultraviolet ray emitting diodes. Then, in order to generate uniform light at such an occasion, the ultraviolet ray emitting diodes have low directivity and perform irradiation by diffusing an ultraviolet ray. Due to this, in the laminate modeling method, when the ultraviolet ray emitting diode according to the related art is used, there is a case where the ultraviolet ray emitted at a specific angle is reflected by a tilted surface and the like of an already-formed three-dimensional modeled object, and enters an ink jet head that discharges ultraviolet curable ink. In this case, the ultraviolet ray (stray light) that has entered the ink jet head cures the ultraviolet curable ink within the ink jet head that has not yet been discharged, and a problem that the printing of the ultraviolet curable ink is inhibited may occur.

The present invention has been made in view of the above problem, and primarily aims to provide a technique for preventing the stray light from being generated from the ultraviolet ray emitting diode.

Based on our original ideas, the present inventors have conceived of the idea that emission of an ultraviolet ray at such an angle that causes stray light can be prevented when directivity in at least a specific direction can be improved in an ultraviolet ray emitting diode, and the generation of the stray light can be prevented not just in a case of manufacturing three-dimensional modeled objects, but also in various circumstances.

However, when a lens that entirely covers a plurality of ultraviolet ray emitting diodes is arranged on the plurality of ultraviolet ray emitting diodes that is aligned, a distance from the ultraviolet ray emitting diodes to a tip of the lens becomes long, so intensity of the ultraviolet ray emitted from the tip of the lens is attenuated, and there is a problem that efficiency is deteriorated.

Thus, as a result of keen examination, the present inventors have conceived of a novel ultraviolet ray emitting diode unit, and have completed the present invention.

In the ultraviolet ray emitting diode unit according to the present invention, in a cross section of the transparent member that includes the optical axis and that is vertical to a second direction that vertically intersects with both the optical axis and the first direction, the width in the optical axis direction of the center portion including the optical axis is preferably shorter than the width in the optical axis direction of the peripheral portion that is farther away from the optical axis than the center portion.

According to the above configuration, in the cross section of the transparent member that includes the optical axis and that is vertical to the second direction, the width in the optical axis direction (thickness) of the center portion is made shorter (thinner) than the width in the optical direction (thickness) of the peripheral portion. Due to this, the transparent member functions as a concave lens for the ultraviolet ray passing through the cross section, and the ultraviolet ray is diffused in the first direction within the cross section, and the uniform irradiation becomes possible. Accordingly, according to the above configuration, the directivity is improved to prevent the stray light in a plane that is vertical to the first direction, and the ultraviolet ray can be diffused to perform uniform irradiation in a plane that is vertical to the second direction.

In the ultraviolet ray emitting diode unit according to the present invention, in the cross section of the transparent member that includes the optical axis and that is vertical to the second direction that vertically intersects with both the optical axis and the first direction, the width in the optical axis direction of the center portion including the optical axis is preferably longer than or identical to the width in the optical axis direction of the peripheral portion that is farther away from the optical axis than the center portion.

According to the above configuration, in the cross section of the transparent member that includes the optical axis and that is vertical to the second direction, the width in the optical axis direction (thickness) of the center portion is longer (thicker) than or identical to the width in the optical direction (thickness) of the peripheral portion. In this mode as well, the directivity can be improved to prevent the stray light in the plane that is vertical to the first direction.

In the ultraviolet ray emitting diode unit according to the present invention, the transparent member may seal the ultraviolet ray emitting diode.

Accordingly, the ultraviolet ray emitting diode unit according to the present invention includes the ultraviolet ray emitting diode, and the transparent member that seals the ultraviolet ray emitting diode, wherein a cross sectional shape of the transparent member that is vertical to the first direction that vertically intersects with the optical axis of the ultraviolet ray emitting diode may be convex in an emitting direction of the ultraviolet ray.

According to the above configuration, due to the cross sectional shape of the transparent member that is vertical to the first direction (that is, a cross section in the second direction that vertically intersects with the first direction) being convex in the emitting direction of the ultraviolet ray, the transparent member serves as a lens, and the directivity in the second direction that vertically intersects with the optical axis and the first direction is improved. When the directivity in at least a specific direction can be improved, the ultraviolet ray can be prevented from being emitted at such an angle that causes the stray light, and the generation of the stray light may be prevented. Thus, according to the above configuration, the stray light can be prevented from being generated from the ultraviolet ray emitting diode.

Furthermore, in the ultraviolet ray emitting diode unit according to the present invention, a cross sectional shape that is vertical to the second direction that vertically intersects with the optical axis of the ultraviolet ray emitting diode and the first direction may be concave in the emitting direction of the ultraviolet ray.

Furthermore, in the ultraviolet ray emitting diode unit according to the present invention, the cross sectional shape that is vertical to the second direction that vertically intersects with the optical axis of the ultraviolet ray emitting diode and the first direction may be flat or trapezoidal on an emitting direction side of the ultraviolet ray.

According to the above configuration, due to the cross sectional shape of the transparent member that is vertical to the first direction being convex, and the cross sectional shape of the transparent member that is vertical to the second direction being concave, flat, or trapezoidal, the transparent member serves as a lens and while the ultraviolet ray is diffused in the first direction to enable uniform irradiation, the directivity can be increased in the second direction to prevent the generation of the stray light. Due to this, the uniform ultraviolet ray irradiation can be realized in the first direction and the prevention of the generation of the stray light can be realized in the second direction.

A set of ultraviolet ray emitting diode units according to the present invention includes a plurality of the ultraviolet ray emitting diode units according to the present invention, being arranged to align along a first direction.

According to the above configuration, since the ultraviolet ray emitting diode units with high directivity in a second direction are aligned in the first direction that vertically intersects with the second direction, the directivity in the second direction becomes high also in the entire set of ultraviolet ray emitting diode units. Due to this, the directivity in a specific direction can be improved also in the set of ultraviolet ray emitting diode units including the plurality of ultraviolet ray emitting diode units, and the generation of the stray light can be prevented.

Especially, in a transparent member of each of the ultraviolet ray emitting diode units, when a cross sectional shape that is vertical to the second direction is concave, the directivity in the second direction can be increased and the uniform ultraviolet ray irradiation can be performed in the first direction.

An ink jet device according to the present invention includes an ink jet head that discharges ultraviolet curable ink; and the ultraviolet ray emitting diode unit according to the present invention or the set of ultraviolet ray emitting diode units according to the present invention arranged on at least one of a front side and a rear side in a scanning direction of the ink jet head, wherein a first direction vertically intersects with the scanning direction.

According to the above configuration, in the ultraviolet ray emitting diode unit, since the directivity in a second direction that vertically intersects with the first direction, that is, in the scanning direction, is high, the generation of the stray light entering the ink jet head existing on the front side or the rear side in the scanning direction with respect to the ultraviolet ray emitting diode unit can be prevented. Due to this, inhibition of the printing of the ultraviolet curable ink by the ink jet head can be suppressed.

Especially, in a transparent member of the ultraviolet ray emitting diode unit, when a cross sectional shape that is vertical to the second direction is concave, the ultraviolet ray emitting diode unit performs uniform ultraviolet ray irradiation in the first direction, so the printed ultraviolet curable ink can suitably be cured.

A three-dimensional modeled object manufacturing device according to the present invention includes the ink jet device according to the present invention, and manufactures a three-dimensional modeled object by a laminate modeling method.

According to the above configuration, the generation of the stray light can be prevented even in a three-dimensional modeled object manufacturing device in which the stray light entering an ink jet head is easily generated by reflection from an inclined surface and the like of an already-formed three-dimensional modeled object.

According to the present invention, generation of stray light from the ultraviolet ray emitting diode can be prevented.

### <Ultraviolet Ray Emitting Diode Unit According to the Present Invention>

An ultraviolet ray emitting diode unit according to the present invention includes a single ultraviolet ray emitting diode; and a single transparent member arranged to include an optical axis of the ultraviolet ray emitting diode, and in a cross section of the transparent member that includes the optical axis and that is vertical to a first direction that vertically intersects with the optical axis, a width in an optical axis direction of a center portion including the optical axis is longer than a width in the optical axis direction of a peripheral portion that is farther away from the optical axis than the center portion. In the cross section of the transparent member that includes the optical axis and that is vertical to the first direction, the width in the optical axis direction (thickness) of the center portion is made longer (thicker) than the width in the optical axis direction (thickness) of the peripheral portion. Due to this, the transparent member functions as a convex lens for ultraviolet ray passing through the cross section, and directivity in a second direction that vertically intersects with the first direction within the cross section is improved. Accordingly, according to the above configuration, since the directivity in a specific direction can be improved, the ultraviolet ray can easily be prevented from being emitted at such an angle that causes the stray light. Thus, according to the above configuration, the stray light can be prevented from being generated from the ultraviolet ray emitting diode. Furthermore, since the single transparent member is combined with the single ultraviolet ray emitting diode, a size of the transparent member can be made small compared to a case where a lens that entirely covers a plurality of ultraviolet ray emitting diodes is arranged on the plurality of ultraviolet ray emitting diodes that is aligned. Due to this, the deterioration in efficiency of the ultraviolet ray emitting diode unit can be avoided.

The ultraviolet ray emitting diode is also referred to an UVLED (Ultra Violet Light Emitting Diode), and is a light emitting diode that performs irradiation of an ultraviolet ray. The ultraviolet ray emitting diode used in the present embodiment is not particularly limited in a light emitting wavelength and the like, and those well known can be used.

The transparent member is a member for efficiently extracting the ultraviolet ray, and is arranged to include the optical axis of the ultraviolet ray emitting diode. A substance constituting the transparent member is not particularly limited so long as it is a substance that allows the ultraviolet ray to penetrate, and may for example be a transparent resin. Furthermore, in an embodiment, the transparent member may seal and protect the ultraviolet ray emitting diode.

Furthermore, other than the above, the ultraviolet ray emitting diode unit may include a substrate and the like for fixation of the ultraviolet ray emitting diode and the transparent member, power supply, temperature detection and the like.

Furthermore, generally, the ultraviolet ray emitting diode unit is often configured to perform plane emission via a sapphire substrate in which a light emitting surface is substantially a top surface.

### First Embodiment

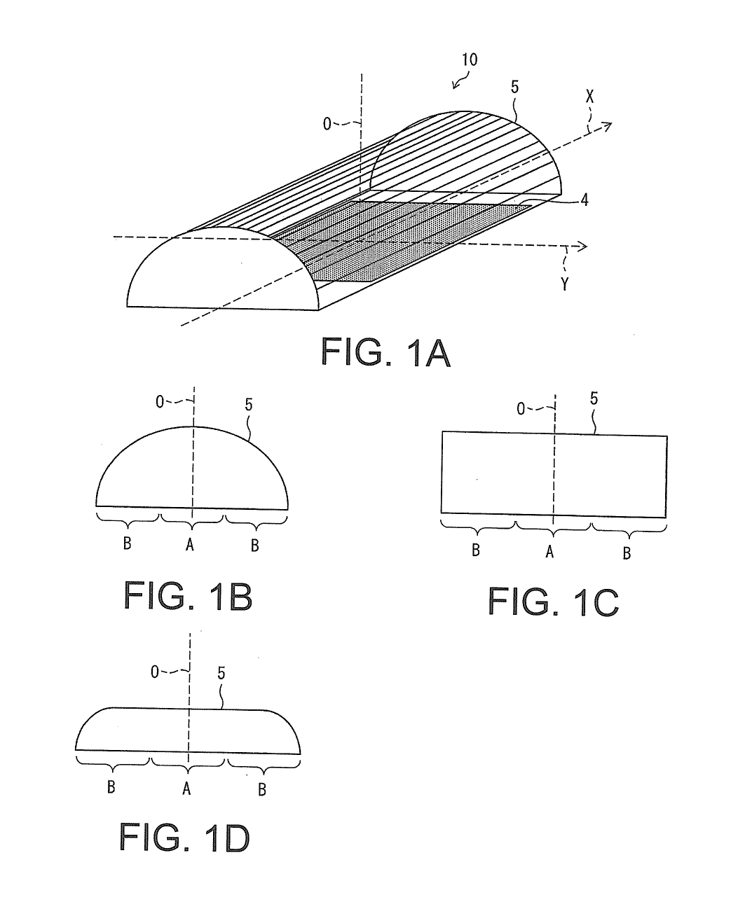

FIGS. 1A to 1C are schematic diagrams showing a general configuration of an ultraviolet ray emitting diode unit 10 according to an embodiment (first embodiment) of the present invention, where FIG. 1A shows a perspective diagram, FIG. 1B shows a cross sectional diagram that is vertical to an X direction (first direction), and FIG. 1C shows a cross sectional diagram that is vertical to a Y direction (second direction).

As shown in FIG. 1A, the ultraviolet ray emitting diode unit 10 includes an ultraviolet ray emitting diode 4, and a transparent member 5 that seals the ultraviolet ray emitting diode 4. The ultraviolet ray emitting diode 4 performs irradiation of an ultraviolet ray to an upper side of a sheet surface with an optical axis O as the center. Furthermore, the X direction (first direction) that vertically intersects with the optical axis O, and the Y direction (second direction) that vertically intersects with both the optical axis O and the X direction are defined. Furthermore, the transparent member 5 is arranged to include the optical axis O.

As shown in FIG. 1B, in a cross section of the transparent member 5 that includes the optical axis O and that is vertical to the X direction, a width in the optical axis direction (thickness) of a center portion A including the optical axis O is longer (thicker) than a width in the optical axis direction (thickness) of a peripheral portion B that is farther away from the optical axis O than the center portion A. Due to this, the transparent member 5 functions as a convex lens for the ultraviolet ray passing through the cross section, and directivity in the Y direction is improved.

It is to be noted that, herein, the “center portion A including the optical axis O” in the cross section can for example be set as a region that occupies ¼ or more and ½ or less, preferably ⅓, of the entire width in the cross section with the optical axis O as the center. Furthermore, the “peripheral portion B that is farther away from the optical axis O than the center portion A” in the cross section can for example be set as a region on each side of the center portion A, which occupies ¼ or more and ⅜ or less, preferably ⅓, of the entire width in the cross section.

Furthermore, in another aspect, as shown in FIG. 1B, a cross sectional shape of the transparent member 5 that is vertical to the X direction is convex in an emitting direction of the ultraviolet ray. Due to this, in a plane that is vertical to the X direction, in other words, a plane defined by an optical axis O direction and the Y direction, the transparent member 5 serves as a convex lens and the ultraviolet ray emitted from the ultraviolet ray emitting diode 4 is condensed in the vicinity of the optical axis O. Due to this, the directivity in the Y direction is improved.

It is to be noted that a cross sectional shape of the transparent member 5 that is vertical to the Y direction of the ultraviolet ray emitting diode 4 is not particularly limited, and for example, as shown in FIG. 1C, the cross sectional shape may be flat on a side of the emitting direction of the ultraviolet ray. Furthermore, as shown in FIG. 1D, the cross sectional shape may be trapezoidal with shoulder portions in the X direction being moderately shaped. That is, in the cross section of the transparent member 5 that includes the optical axis O and that is vertical to the Y direction, the width in the optical axis direction (thickness) of the center portion A including the optical axis O may be longer than or identical to the width in the optical axis direction (thickness) of the peripheral portion B.

### Second Embodiment

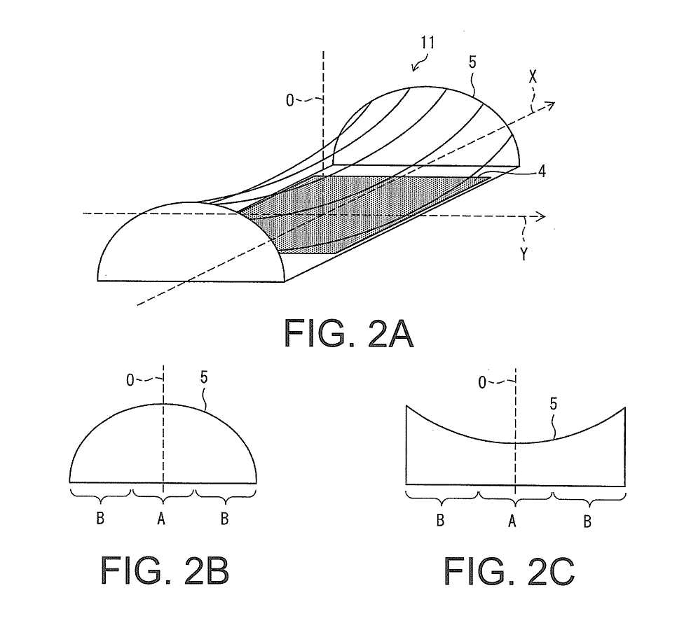

FIGS. 2A to 2C are schematic diagrams showing a general configuration of an ultraviolet ray emitting diode unit 11 according to another embodiment (second embodiment) of the present invention, where FIG. 2A shows a perspective diagram, FIG. 2B shows a cross sectional diagram that is vertical to an X direction (first direction), and FIG. 2C shows a cross sectional diagram that is vertical to a Y direction (second direction).

As shown in FIG. 2A, the ultraviolet ray emitting diode unit 11 includes an ultraviolet ray emitting diode 4, and a transparent member 5 that seals the ultraviolet ray emitting diode 4. Furthermore, the transparent member 5 is arranged to include an optical axis O. The ultraviolet ray emitting diode unit 11 differs from the ultraviolet ray emitting diode unit 10 of the first embodiment in the shape of the transparent member 5.

As shown in FIG. 2B, in a cross section of the transparent member 5 that includes the optical axis O and that is vertical to the X direction, a width in an optical axis direction (thickness) of a center portion A including the optical axis O is longer (thicker) than a width in the optical axis direction (thickness) of a peripheral portion B that is farther away from the optical axis O than the center portion A. Due to this, the transparent member 5 functions as a convex lens for an ultraviolet ray passing through the cross section, and directivity in the Y direction is improved.

Furthermore, in another aspect, as shown in FIG. 2B, a cross sectional shape of the transparent member 5 that is vertical to the X direction is convex in an emitting direction of the ultraviolet ray. Due to this, in a plane that is vertical to the X direction, in other words, a plane defined by the optical axis O and the Y direction, the transparent member 5 serves as a convex lens and the ultraviolet ray emitted from the ultraviolet ray emitting diode 4 is condensed in the vicinity of the optical axis O. Due to this, the directivity in the Y direction is improved.

Furthermore, as shown in FIG. 2C, in a cross section of the transparent member 5 that includes the optical axis O and that is vertical to the Y direction, the width in the optical axis direction (thickness) of the center portion A including the optical axis O is shorter (thinner) than the width in the optical axis direction (thickness) of the peripheral portion B that is farther away from the optical axis O than the center portion A. Due to this, the transparent member 5 functions as a concave lens for the ultraviolet ray passing through the cross section, and directivity in the X direction is reduced.

Furthermore, in another aspect, as shown in FIG. 2C, a cross sectional shape of the transparent member 5 that is vertical to the Y direction is concave in the emitting direction of the ultraviolet ray. Due to this, in a plane that is vertical to the Y direction, in other words, a plane defined by the optical axis O and the X direction, the transparent member 5 serves as a concave lens and the ultraviolet ray emitted from the ultraviolet ray emitting diode 4 is diffused. Due to this, the directivity in the X direction is reduced.

Due to this, in the ultraviolet ray emitting diode unit 11, the ultraviolet ray is diffused in the X direction to enable uniform irradiation, and the directivity can be increased in the Y direction to prevent the generation of the stray light. Due to this, the uniform ultraviolet ray irradiation can be realized in the X direction while the prevention of the generation of the stray light can be realized in the Y direction.

### Modification of Second Embodiment

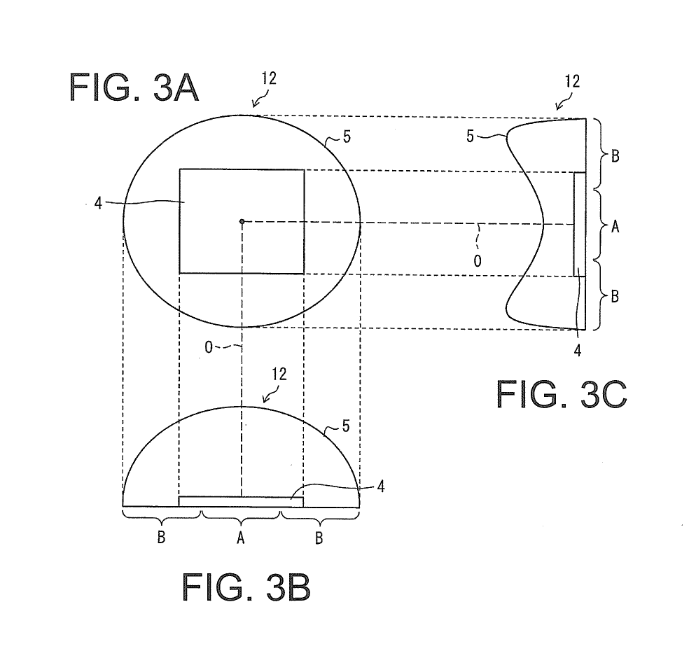

FIGS. 3A to 3C are schematic diagrams showing a general configuration of an ultraviolet ray emitting diode unit 12 according to a modification of the second embodiment, where FIG. 3A shows a top view diagram, FIG. 3B shows a cross sectional diagram that is vertical to an X direction (first direction), and FIG. 3C shows a cross sectional diagram that is vertical to a Y direction (second direction).

As shown in FIGS. 3A to 3C, the ultraviolet ray emitting diode unit 12 has a structure in which a periphery of a transparent member 5 is rounded, compared to the ultraviolet ray emitting diode unit 11 of the second embodiment.

Here, even when the periphery of the transparent member 5 is rounded, in a plane that is vertical to the Y direction, in other words, a plane that is defined by an optical axis O and the X direction, since the transparent member 5 serves as a concave lens in a periphery of the optical axis O, the transparent member 5 serves as the concave lens in a similar manner to the ultraviolet ray emitting diode unit 11 of the embodiment 2, and an ultraviolet ray emitted from an ultraviolet ray emitting diode 4 is diffused.

Furthermore, even when the periphery of the transparent member 5 is rounded, a cross sectional shape of the transparent member 5 that is vertical to the X direction is convex in an emitting direction of the ultraviolet ray, and in a plane that is vertical to the X direction, in other words, a plane that is defined by the optical axis O and the Y direction, the transparent member 5 serves as a convex lens in a similar manner to the ultraviolet ray emitting diode unit 10 of the first embodiment and the ultraviolet ray emitting diode unit 11 of the second embodiment, and light is condensed in the vicinity of the optical axis.

Thus, the ultraviolet ray emitting diode unit 12 diffuses the ultraviolet ray in the X direction to enable uniform irradiation and can prevent the generation of the stray light by increasing the directivity in the Y direction, in a similar manner to the ultraviolet ray emitting diode unit 11 of the second embodiment. Due to this, the uniform ultraviolet ray irradiation can be realized in the X direction while the prevention of the generation of the stray light can be realized in the Y direction.

According to the above, in the present invention, the cross sectional shape of the transparent member 5 being convex or concave in the emitting direction of the ultraviolet ray means that a portion including the optical axis in the transparent member 5 is projecting or recessed contrary to the ultraviolet ray emitting diode 4, and more preferably means being projecting or recessed with respect to the ultraviolet ray emitting diode 4 in a range of ±15°, ±30°, or ±45° or more of the transparent member 5 from the ultraviolet ray emitting diode 4 with the optical axis as the center.

Furthermore, the ultraviolet ray emitting diode 4 does not only include one ultraviolet ray emitting diode, but may include a plurality (for example, two or four) ultraviolet ray emitting diodes. In other words, there may be the single transparent member 5 functioning as a lens for the plurality of ultraviolet ray emitting diodes.

Furthermore, in another aspect, as shown in FIG. 3B, in a cross section of the transparent member 5 that includes the optical axis O and that is vertical to the X direction, the width in an optical axis direction (thickness) of a center portion A may be longer (thicker) than the width in the optical axis direction (thickness) of a peripheral portion B, the transparent member 5 functions as the convex lens for the ultraviolet ray passing through the cross section, and the directivity in the Y direction is improved. Furthermore, as shown in FIG. 3C, in a cross section of the transparent member 5 that includes the optical axis O and that is vertical to the Y direction, the width in the optical axis direction (thickness) of the center portion A is shorter (thinner) than the width in the optical axis direction (thickness) of the peripheral portion B, the transparent member 5 functions as the concave lens for the ultraviolet ray passing through the cross section, and the directivity in the X direction is reduced. Thus, the uniform ultraviolet ray irradiation can be realized in the X direction while the prevention of the generation of the stray light can be realized in the Y direction.

### Third Embodiment

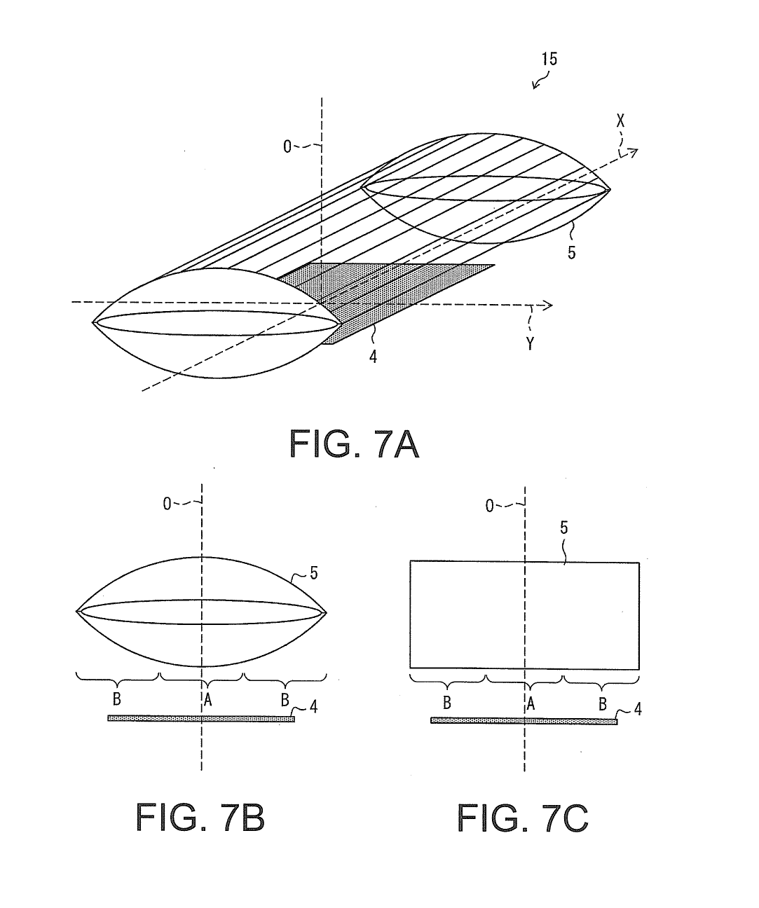

FIGS. 7A to 7C are schematic diagrams showing a general configuration of an ultraviolet ray emitting diode unit 15 according to an embodiment (third embodiment) of the present invention, where FIG. 7A shows a perspective diagram, FIG. 7B shows a cross sectional diagram that is vertical to an X direction (first direction), and FIG. 7C shows a cross sectional diagram that is vertical to a Y direction (second direction).

As shown in FIG. 7A, the ultraviolet ray emitting diode unit 15 includes an ultraviolet ray emitting diode 4, and a transparent member 5 arranged to include an optical axis O while not sealing the ultraviolet ray emitting diode 4. The ultraviolet ray emitting diode unit 15 differs from the ultraviolet ray emitting diode unit 10 of the first embodiment in the arrangement and shape of the transparent member 5.

A method for arranging the transparent member 5 so as to include the optical axis O while not sealing the ultraviolet ray emitting diode 4 is not specifically limited, and for example, the transparent member 5 may be supported from outside by using a support member (not shown) which supports the transparent member 5. Furthermore, a space between the transparent member 5 and the ultraviolet ray emitting diode 4 may be filled with a substance having a refractive index closer to air than the transparent member 5.

As shown in FIG. 7B, in a cross section of the transparent member 5 that includes the optical axis O and that is vertical to the X direction, the width in an optical axis direction (thickness) of a center portion A including the optical axis O is longer (thicker) than the width in the optical axis direction (thickness) of a peripheral portion B that is farther away from the optical axis O than the center portion A. Due to this, the transparent member 5 functions as a convex lens for an ultraviolet ray passing through the cross section, and directivity in the Y direction is improved.

It is to be noted that, in FIG. 7B, the configuration in which the cross section of the transparent member 5 that includes the optical axis O and that is vertical to the X direction has the cross sectional shape of a biconvex lens is shown; however, the present embodiment is not limited thereto so long as the width in the optical axis direction (thickness) of the center portion A is longer than the width in the optical axis direction (thickness) of the peripheral portion B in the cross section. For example, the cross section of the transparent member 5 that includes the optical axis O and that is vertical to the X direction may have the cross sectional shape of a plano-convex lens that is projecting with respect to the ultraviolet ray emitting diode 4, may have the cross sectional shape of a plano-convex lens that is projecting with respect to an opposite side to the ultraviolet ray emitting diode 4, may have the cross sectional shape of a biconvex lens, or may have the cross sectional shape of a convex meniscus lens.

As above, the ultraviolet ray emitting diode unit 15 can prevent the generation of the stray light by increasing the directivity in the Y direction.

Furthermore, as shown in FIG. 7C, in a cross section of the transparent member 5 that includes the optical axis O and that is vertical to the Y direction, the width in the optical axis direction (thickness) of the center portion A including the optical axis O may be identical to the width in the optical axis direction (thickness) of the peripheral portion B that is farther away from the optical axis O than the center portion A. However, the present invention is not limited thereto, and the width in the optical axis direction (thickness) of the center portion A may be longer than or shorter than the width in the optical axis direction (thickness) of the peripheral portion B in the cross section of the transparent member 5 that includes the optical axis O and that is vertical to the Y direction.

It is to be noted that, so long as the width in the optical axis direction (thickness) of the center portion A is shorter (thinner) than the width in the optical axis direction (thickness) of the peripheral portion B, the transparent member 5 functions as a concave lens for the ultraviolet ray passing through the cross section, and the directivity in the X direction is reduced. At this occasion, the cross section of the transparent member 5 that includes the optical axis O and that is vertical to the X direction may have the cross sectional shape of a plano-concave lens that is recessed with respect to the ultraviolet ray emitting diode 4, may have the cross sectional shape of a plano-concave lens that is recessed with respect to an opposite side to the ultraviolet ray emitting diode 4, may have the cross sectional shape of a biconcave lens, or may have the cross sectional shape of a concaved meniscus lens. Due to this, the uniform ultraviolet ray irradiation in the X direction can be realized.

### <Set of Ultraviolet Ray Emitting Diode Units According to the Present Invention>

A set of ultraviolet ray emitting diode units according to the present invention includes a plurality of the ultraviolet ray emitting diode units according to the present invention, being arranged to align along a first direction. Since the ultraviolet ray emitting diode units with high directivity in a second direction are aligned in the first direction that vertically intersects with the second direction, the directivity in the second direction becomes high also in the entire set of ultraviolet ray emitting diode units. Due to this, the directivity in a specific direction can be improved also in the set of ultraviolet ray emitting diode units including the plurality of ultraviolet ray emitting diode units, and the generation of the stray light can be prevented.

### Fourth Embodiment

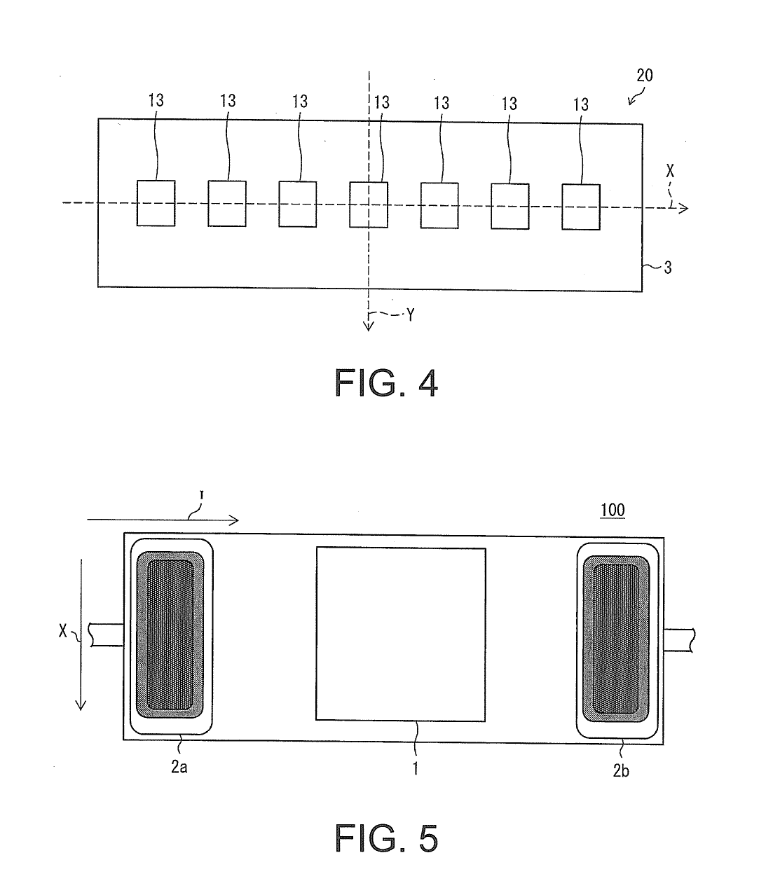

FIG. 4 is a schematic diagram showing a general configuration of a set 20 of ultraviolet ray emitting diode units according to an embodiment (fourth embodiment) of the present invention.

As shown in FIG. 4, the set 20 of ultraviolet ray emitting diode units includes a plurality of ultraviolet ray emitting diode units 13 arranged to align along an X direction (first direction). The plurality of ultraviolet ray emitting diode units 13 is arranged to align on a substrate 3. The X direction (first direction) that vertically intersects with optical axes O of the ultraviolet ray emitting diode units 13, and a Y direction (second direction) that vertically intersects with both the optical axes O and the X direction are defined on the substrate 3.

It is to be noted that, in FIG. 4, the ultraviolet ray emitting diode units 13 are arranged in one line; however, the ultraviolet ray emitting diode units 13 may be provided in plural lines in order to increase light emission, the exposure width, and the like.

Each of the ultraviolet ray emitting diode units 13 is an ultraviolet ray emitting diode unit that is similar to the ultraviolet ray emitting diode unit 10 of the first embodiment, the ultraviolet ray emitting diode units 11 and 12 of the second embodiment, and the ultraviolet ray emitting diode unit 15 of the third embodiment, and has high directivity in the Y direction (second direction). Due to this, the directivity in the Y direction (second direction) becomes high also in the entire set 20 of ultraviolet ray emitting diode units. Due to this, the directivity in a specific direction can be improved, and the generation of the stray light can be prevented.

Especially, in a case where each of the ultraviolet ray emitting diode units 13 has a cross sectional shape that is vertical to the Y direction and that is concave (for example, each of the ultraviolet ray emitting diode units 13 has the same configuration as the ultraviolet ray emitting diode units 11 and 12 of the second embodiment), the directivity in the X direction (first direction) is low, so the directivity can be increased in the Y direction (second direction) while performing uniform ultraviolet ray irradiation in the X direction (first direction).

### <Ink Jet Device According to the Present Invention>

An ink jet device according to the present invention includes an ink jet head that discharges ultraviolet curable ink; and the ultraviolet ray emitting diode unit according to the present invention or the set of ultraviolet ray emitting diode units according to the present invention, which is arranged on at least one of a front side and a rear side in a scanning direction of the ink jet head, and a first direction vertically intersects with the scanning direction. In the ultraviolet ray emitting diode unit, since the directivity in a second direction that vertically intersects with the first direction, that is, in the scanning direction, is high, the generation of the stray light entering into the ink jet head existing on the front side or the rear side in the scanning direction with respect to the ultraviolet ray emitting diode unit can be prevented. Due to this, inhibition of the printing of the ultraviolet curable ink by the ink jet head can be suppressed.

### Fifth Embodiment

FIG. 5 is a schematic diagram showing a configuration of a main part of an ink jet device 100 according to an embodiment (fifth embodiment) of the present invention. As shown in FIG. 5, the ink jet device 100 includes an ink jet head 1 that discharges ultraviolet curable ink; and sets 2a and 2b of ultraviolet ray emitting diode units arranged on a front side and a rear side in a scanning direction of the ink jet head 1 (Y direction). As in the set 20 of ultraviolet ray emitting diode units of the third embodiment, each of the sets 2a and 2b of ultraviolet ray emitting diode units has a plurality of ultraviolet ray emitting diode units 14 arranged to align along an X direction (first direction). It is to be noted that, the present embodiment is not limited thereto, and may have a configuration in which only one of the sets 2a and 2b of ultraviolet ray emitting diode units is provided.

In the ink jet device 100, the scanning direction (Y direction) that is a direction along which the ink jet head 1 and the sets 2a and 2b of ultraviolet ray emitting diode units scan, and a sub-scanning direction (X direction) that vertically intersects with the scanning direction are defined, where the X direction (first direction) in the ultraviolet ray emitting diode units 14 is parallel to the sub-scanning direction, and the Y direction (second direction) in the ultraviolet ray emitting diode units 14 is parallel to the scanning direction.

The ink jet head 1 is not particularly limited so long as the ultraviolet curable ink may be printed, and a well known ink jet head can be used. Examples thereof include an ink jet head that discharges liquid droplets by using oscillation of a piezoelectric element (an ink jet head that forms ink droplets by mechanical deformation of an electrostrictive element), and an ink jet head that uses thermal energy.

It is to be noted that, in FIG. 5, the ink jet head 1 and the sets 2a and 2b of ultraviolet ray emitting diode units are mounted on the same member (carriage); however, they may be mounted on different members.

In addition, the ink jet device 100 may include a platen which supports a print object medium, units which relatively move the print object medium with respect to the ink jet head 1 (a roller, a Y bar driving unit and the like), and it may be a roller device, or a flatbed device.

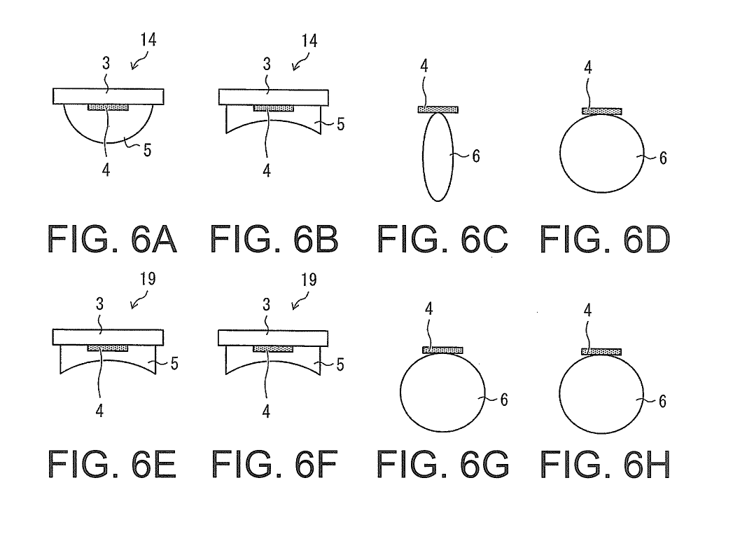

Next, the present embodiment and the related art will be compared to describe the effect of the ink jet device 100 according to the present embodiment. FIG. 6A to 6H are diagrams showing a relationship of structures of ultraviolet ray emitting diode units according to the present embodiment and the related art and directivity of an ultraviolet ray for irradiation.

Firstly, a case of using an ultraviolet ray emitting diode unit 19 according to the related art will be described.

FIG. 6E is a diagram showing a cross sectional shape of the ultraviolet ray emitting diode unit 19 that is vertical to the X direction. FIG. 6G is a diagram showing the directivity of the ultraviolet ray of the ultraviolet ray emitting diode unit 19 in a plane that is vertical to the X direction, in other words, the directivity of the ultraviolet ray in the Y direction.

As shown in FIG. 6E, a cross sectional shape of a transparent member 5 that is vertical to the X direction is concave in an emitting direction of the ultraviolet ray. Due to this, as shown in FIG. 6G, the directivity of an ultraviolet ray 6 emitted from the ultraviolet ray emitting diode unit 19 in the Y direction is reduced.

FIG. 6F is a diagram showing a cross sectional shape of the ultraviolet ray emitting diode unit 19 that is vertical to the Y direction. FIG. 6H is a diagram showing the directivity of the ultraviolet ray of the ultraviolet ray emitting diode unit 19 in a plane that is vertical to the Y direction, in other words, the directivity of the ultraviolet ray in the X direction.

As shown in FIG. 6F, a cross sectional shape of the transparent member 5 that is vertical to the Y direction is concave in the emitting direction of the ultraviolet ray. Due to this, as shown in FIG. 6H, the directivity of the ultraviolet ray 6 emitted from the ultraviolet ray emitting diode unit 19 in the X direction is reduced.

Accordingly, in the ultraviolet ray emitting diode unit 14, since the directivity in the Y direction that vertically intersects with the X direction, that is, the scanning direction, is low, there is a risk that the stray light may be emitted from the ultraviolet ray emitting diode unit 14 in the scanning direction. Due to this, there is a risk that the stray light that enters the ink jet head 1 present on the front side or the rear side in the scanning direction with respect to the ultraviolet ray emitting diode unit 14 may be generated, and there is a risk that the printing of the ultraviolet curable ink by the ink jet head 1 may be inhibited.

In contrast, FIG. 6A is a diagram showing a cross sectional shape of the ultraviolet ray emitting diode unit 14 that is vertical to the X direction. FIG. 6C is a diagram showing the directivity of the ultraviolet ray of the ultraviolet ray emitting diode unit 14 in the plane that is vertical to the X direction, in other words, the directivity of the ultraviolet ray in the Y direction.

As shown in FIG. 6A, the cross sectional shape of the transparent member 5 that is vertical to the X direction is convex in the emitting direction of the ultraviolet ray. Due to this, as shown in FIG. 6C, the directivity of the ultraviolet ray 6 emitted from the ultraviolet ray emitting diode unit 14 in the Y direction is increased.

FIG. 6B is a diagram showing a cross sectional shape of the ultraviolet ray emitting diode unit 14 that is vertical to the Y direction. FIG. 6D is a diagram showing the directivity of the ultraviolet ray of the ultraviolet ray emitting diode unit 14 in the plane that is vertical to the Y direction, in other words, the directivity of the ultraviolet ray in the X direction.

As shown in FIG. 6B, the cross sectional shape of the transparent member 5 that is vertical to the Y direction is concave in the emitting direction of the ultraviolet ray. Due to this, as shown in FIG. 6D, the directivity of the ultraviolet ray 6 emitted from the ultraviolet ray emitting diode unit 14 in the X direction is reduced.

Accordingly, in the ultraviolet ray emitting diode unit 14, since the directivity in the Y direction that vertically intersects with the X direction, that is, in the scanning direction, is high, emission of the stray light from the ultraviolet ray emitting diode unit 14 in the scanning direction can be suppressed. Due to this, the generation of the stray light entering the ink jet head 1 present on the front side or the rear side in the scanning direction with respect to the ultraviolet ray emitting diode unit 14 can be prevented. Due to this, inhibition of the printing of the ultraviolet curable ink by the ink jet head 1 can be suppressed.

Further, in the transparent member 5 of the ultraviolet ray emitting diode unit 14, since the cross sectional shape that is vertical to the Y direction is concave, the directivity of the ultraviolet ray emitting diode unit 14 in the Y direction is low, and the uniform ultraviolet ray irradiation can be performed thoroughly in the X direction. Due to this, the printed ultraviolet curable ink can suitably be cured.

It is to be noted that, in the present embodiment, the configuration in which the ultraviolet ray emitting diode unit 14 has the same structure as the ultraviolet ray emitting diode unit 11 described in the second embodiment has been described; however, the present embodiment is not limited thereto, and it is only necessary that the ultraviolet ray emitting diode unit 14 includes a single ultraviolet ray emitting diode; and a single transparent member arranged to include an optical axis of the ultraviolet ray emitting diode, wherein in a cross section of the transparent member that includes the optical axis and that is vertical to a first direction that vertically intersects with the optical axis, a width in the optical axis direction of a center portion including the optical axis is longer than a width in the optical axis direction of a peripheral portion that is farther away from the optical axis than the center portion. For example, the ultraviolet ray emitting diode unit 14 may have the same structure as the ultraviolet ray emitting diode unit 10 described in the first embodiment, the ultraviolet ray emitting diode unit 12 described in the modification of the second embodiment, or the ultraviolet ray emitting diode unit 15 described in the third embodiment.

### <Three-Dimensional Modeled Object Manufacturing Device of Present Invention>

A three-dimensional modeled object manufacturing device according to the present invention includes the ink jet device according to the present invention, and manufactures a three-dimensional modeled object by a laminate modeling method. In other words, the three-dimensional modeled object manufacturing device according to the present invention includes an ink jet head that discharges ultraviolet curable ink; and the ultraviolet ray emitting diode unit according to the present invention or the set of ultraviolet ray emitting diode units according to the present invention, which is arranged on at least one of a front side and a rear side in a scanning direction of the ink jet head, wherein a first direction vertically intersects with the scanning direction; and manufactures a three-dimensional modeled object by a laminate modeling method. Due to this, the generation of the stray light can be prevented even in a three-dimensional modeled object manufacturing device in which the stray light entering the ink jet head by reflection from an inclined surface and the like of an already-formed three-dimensional modeled object is easily generated.

In an embodiment, the three-dimensional modeled object manufacturing device according to the present invention can be realized by the ink jet device 100 of the fourth embodiment. For example, the three-dimensional modeled object manufacturing device according to the embodiment of the present invention uses the ink jet device 100 of the fourth embodiment to manufacture the three-dimensional modeled object by laminating print layers that are formed by printing and curing the ultraviolet curable ink that is to be a modeling material.

Specifically, the three-dimensional modeled object manufacturing device firstly uses the ink jet head 1 to print the ultraviolet curable ink that is to be the modeling material on a medium, and irradiates the printed ultraviolet curable ink with the ultraviolet ray to cure the same by the sets 2a and 2b of ultraviolet ray emitting diode units including the ultraviolet ray emitting diode units 14. At this occasion, as described above, the stray light entering the ink jet head 1 can be suppressed because the directivity of the ultraviolet ray emitted in the scanning direction from the ultraviolet ray emitting diode units 14 is high. Then, the three-dimensional modeled object can be manufactured by repeating this printing and curing of the ultraviolet curable ink.

It is to be noted that, in an embodiment, a support material that is to be a support body for the modeling material may be printed by the ink jet head 1. A structure of the modeling material is supported by the support material and after the modeling material is cured so that the modeling material can maintain a structure of a modeled object, the support material is removed as needed.

For the support material, a water-swellable gel, wax, a thermoplastic resin, an aqueous material, a soluble material, ultraviolet ray curing type ink that can be removed by remover solution such as water, alkali liquid, and an organic solvent after curing, and the like may be used as a removable material. Among them, since it is also desirable that the support material cure quickly and easily in order to support the modeling material, the ultraviolet ray curing type ink is preferable. For the removal of the support material, methods such as dissolution by water, heating, chemical reaction, motive power cleansing such as jet cleansing and the like, and dissolution by irradiation of electromagnetic waves, separation using thermal expansion difference and the like can suitably be used according to the nature of the support material. In a case of using the ultraviolet ray curing type ink as the modeling material, it may suitably be removed by a corresponding solvent as being aqueous, or solvent-soluble in advance.

Also in the curing of the ultraviolet ray curing type ink in the case of using the ultraviolet ray curing type ink as the support material, for example, the stray light entering the ink jet head 1 can be suppressed by using the sets 2a and 2b of ultraviolet ray emitting diode units including the ultraviolet ray emitting diode units 14.

The present invention is not limited to the respective embodiments described above. Various modifications can be made within the scope of the claims, and embodiments obtained by suitably combining the technical features disclosed respectively in the different embodiments are also included in the technical scope of the present invention.

### Supplemental Information

As above, the ultraviolet ray emitting diode unit (10, 11, 12, 13, 14 or 15) according to an embodiment of the present invention includes the single ultraviolet ray emitting diode 4, and the single transparent member 5 arranged to include the optical axis O of the ultraviolet ray emitting diode 4, and in the cross section of the transparent member 5 that includes the optical axis O and that is vertical to the X direction that vertically intersects with the optical axis O, the width in the optical axis direction of the center portion A including the optical axis O is longer than the width in the optical axis direction of the peripheral portion B that is farther away from the optical axis O than the center portion A.

According to the above configuration, in the cross section of the transparent member 5 that includes the optical axis O and that is vertical to the X direction, the width in the optical axis direction (thickness) of the center portion A is made longer (thicker) than the width in the optical axis direction (thickness) of the peripheral portion B. Due to this, the transparent member 5 functions as the convex lens (for example, a plano-convex lens, a biconvex lens, and a convex meniscus lens) for the ultraviolet ray passing through the cross section, and the directivity in the Y direction that vertically intersects with the X direction improves within the cross section. Accordingly, according to the above configuration, since the directivity in a specific direction can be improved, the ultraviolet ray can easily be prevented from being emitted at such an angle that causes the stray light. Thus, according to the above configuration, the stray light can be prevented from being generated from the ultraviolet ray emitting diode 4.

Furthermore, according to the above configuration, since the single transparent member 5 is combined with the single ultraviolet ray emitting diode 4, the size of the transparent member can be made small compared to the case where a lens that entirely covers the plurality of ultraviolet ray emitting diodes is arranged on the plurality of ultraviolet ray emitting diodes 4 that is aligned. Due to this, the deterioration in efficiency of the ultraviolet ray emitting diode unit (10, 11, 12, 13, 14 or 15) can be avoided.

In the ultraviolet ray emitting diode unit (11, 12, 13, 14 or 15) according to an embodiment of the present invention, in the cross section of the transparent member 5 that includes the optical axis O and that is vertical to the Y direction that vertically intersects with both the optical axis O and the X direction, the width in the optical axis direction of the center portion A including the optical axis A is shorter than the width in the optical axis direction of the peripheral portion B that is farther away from the optical axis O than the center portion.

According to the above configuration, in the cross section of the transparent member 5 that includes the optical axis O and that is vertical to the Y direction, the width in the optical axis direction (thickness) of the center portion A is made shorter (thinner) than the width in the optical axis direction (thickness) of the peripheral portion B. Due to this, the transparent member 5 functions as the concave lens (for example, a plano-concave lens, a biconcave lens, a concave meniscus lens and the like) for the ultraviolet ray passing through the cross section, and the ultraviolet ray is diffused in the X direction within the cross section, and unifoiin irradiation becomes possible. Accordingly, according to the above configuration, the directivity is improved to prevent the stray light in the plane that is vertical to the X direction, and the ultraviolet ray can be diffused to perform the uniform irradiation in the plane that is vertical to the Y direction.

In the ultraviolet ray emitting diode unit (10) according to an embodiment of the present invention, in the cross section of the transparent member 5 that includes the optical axis O and that is vertical to the Y direction that vertically intersects with both the optical axis O and the X direction, the width in the optical axis direction of the center portion A including the optical axis O is longer than or identical to the width in the optical axis direction of the peripheral portion B that is farther away from the optical axis O than the center portion A.

According to the above configuration, in the cross section of the transparent member 5 that includes the optical axis O and that is vertical to the Y direction, the width in the optical axis direction (thickness) of the center portion A is longer (thicker) than or identical to the width in the optical axis direction (thickness) of the peripheral portion B. In this mode as well, the directivity can be improved to prevent the stray light in the plane that is vertical to the X direction.

In the ultraviolet ray emitting diode unit (10, 11, 12, 13 or 14) according to an embodiment of the present invention, the transparent member 5 may seal the ultraviolet ray emitting diode 4.

The ultraviolet ray emitting diode unit (10, 11, 12, 13 or 14) according to an embodiment of the present invention includes the ultraviolet ray emitting diode 4, and the transparent member 5 that seals the ultraviolet ray emitting diode 4, and the cross sectional shape of the transparent member 5 that is vertical to the X direction that vertically intersects with the optical axis O of the ultraviolet ray emitting diode 4 is convex in the emitting direction of the ultraviolet ray.

According to the above configuration, due to the cross sectional shape of the transparent member that is vertical to the X direction being convex in the emitting direction of the ultraviolet ray, the transparent member serves as a lens, and the directivity in the Y direction that vertically intersects with the optical axis and the X direction is improved. When the directivity in at least a specific direction can be improved, the ultraviolet ray can be prevented from being emitted at such an angle that causes the stray light, and the generation of the stray light may be prevented. Thus, according to the above configuration, the stray light can be prevented from being generated from the ultraviolet ray emitting diode 4.

In the ultraviolet ray emitting diode unit (11, 12, 13 or 14) according to an embodiment of the present invention, the cross sectional shape that is vertical to the Y direction that vertically intersects with the optical axis O of the ultraviolet ray emitting diode 4 and the X direction is concave in the emitting direction of the ultraviolet ray.

In the ultraviolet ray emitting diode unit according to an embodiment of the present invention, the cross sectional shape that is vertical to the Y direction that vertically intersects with the optical axis O of the ultraviolet ray emitting diode 4 and the first direction is flat or trapezoidal on the emitting direction side of the ultraviolet ray.

According to the above configuration, due to the cross sectional shape of the transparent member 5 that is vertical to the X direction being convex, and the cross sectional shape of the transparent member that is vertical to the Y direction being concave, flat, or trapezoidal, the transparent member 5 serves as a lens, and while the ultraviolet ray is diffused in the X direction to enable uniform irradiation, the directivity can be increased in the Y direction to prevent the generation of the stray light. Due to this, the uniform ultraviolet ray irradiation can be realized in the X direction, and the prevention of the generation of the stray light is realized in the Y direction.

The set (20) of ultraviolet ray emitting diode units according to an embodiment of the present invention includes the plurality of ultraviolet ray emitting diode units 13 arranged to align along the X direction.

According to the above configuration, since the ultraviolet ray emitting diode units 13 with high directivity in the Y direction are aligned in the X direction that vertically intersects with the Y direction, the directivity in the Y direction becomes high also in the entire set 20 of ultraviolet ray emitting diode units. Due to this, the directivity in a specific direction can be improved also in the set 20 of ultraviolet ray emitting diode units including the plurality of ultraviolet ray emitting diode units 13, and the generation of the stray light can be prevented.

Especially, in the transparent members 5 of the ultraviolet ray emitting diode units 13, when the cross sectional shape that is vertical to the Y direction is concave, the directivity in the Y direction can be increased and the uniform ultraviolet ray irradiation can be performed in the X direction.

The ink jet device 100 according to an embodiment of the present invention includes the ink jet head 1 that discharges the ultraviolet curable ink; and the sets 2a and 2b of ultraviolet ray emitting diode units arranged on the front side and the rear side in the scanning direction of the ink jet head 1, and the X direction vertically intersects with the scanning direction.

According to the above configuration, in the ultraviolet ray emitting diode unit 14, since the directivity in the Y direction that vertically intersects with the X direction, that is, in the scanning direction, is high, the generation of the stray light entering the ink jet head 1 existing on the front side or the rear side in the scanning direction with respect to the ultraviolet ray emitting diode unit 14 can be prevented. Due to this, inhibition of the printing of the ultraviolet curable ink by the ink jet head 1 can be suppressed.

Especially, in the transparent member 5 of the ultraviolet ray emitting diode unit 14, when the cross sectional shape that is vertical to the Y direction is concave, the ultraviolet ray emitting diode unit 14 performs uniform ultraviolet ray irradiation in the X direction, so the printed ultraviolet curable ink can suitably be cured.

The three-dimensional modeled object manufacturing device according to an embodiment of the present invention includes the ink jet device 100, and manufactures the three-dimensional modeled object by the laminate modeling method.

According to the above configuration, the generation of the stray light can be prevented even in a three-dimensional modeled object manufacturing device in which the stray light entering the ink jet head 1 is easily generated by reflection from an inclined surface and the like of an already-formed three-dimensional modeled object.

The present invention can be used in fields of manufacturing an ultraviolet ray emitting diode and an apparatus including the ultraviolet ray emitting diode.

What is claimed is:

1. An ultraviolet ray emitting diode unit comprising:
a single ultraviolet ray emitting diode; and
a single transparent member arranged to include an optical axis of the ultraviolet ray emitting diode,
wherein in a cross section of the transparent member that includes the optical axis and that is vertical to a first direction that vertically intersects with the optical axis, a width in an optical axis direction of a center portion including the optical axis is longer than a width in the optical axis direction of a peripheral portion that is farther away from the optical axis than the center portion.

2. The ultraviolet ray emitting diode unit according to claim 1, wherein
in a cross section of the transparent member that includes the optical axis, and that is vertical to a second direction that vertically intersects with both the optical axis and the first direction, the width in the optical axis direction of the center portion including the optical axis is shorter than the width in the optical axis direction of the peripheral portion that is farther away from the optical axis than the center portion.

3. The ultraviolet ray emitting diode unit according to claim 1, wherein
in the cross section of the transparent member that includes the optical axis, and that is vertical to the second direction that vertically intersects with both the optical axis and the first direction, the width in the optical axis direction of the center portion including the optical axis is longer than or identical to the width in the optical axis direction of the peripheral portion that is farther away from the optical axis than the center portion.

4. The ultraviolet ray emitting diode unit according to claim 1, wherein
the transparent member seals the ultraviolet ray emitting diode.

5. A set of ultraviolet ray emitting diode units, the set comprising:
a plurality of the ultraviolet ray emitting diode units according to claim 1, being arranged to align along a first direction.

6. A set of ultraviolet ray emitting diode units, the set comprising:
a plurality of the ultraviolet ray emitting diode units according to claim 2, being arranged to align along a first direction.

7. A set of ultraviolet ray emitting diode units, the set comprising:
a plurality of the ultraviolet ray emitting diode units according to claim 3, being arranged to align along a first direction.

8. An ink jet device comprising:
an ink jet head that discharges ultraviolet curable ink; and
the ultraviolet ray emitting diode unit according to claim 1, which is arranged on at least one of a front side and a rear side in a scanning direction of the ink jet head,
wherein the first direction vertically intersects with the scanning direction.

9. An ink jet device comprising:
an ink jet head that discharges ultraviolet curable ink; and
the ultraviolet ray emitting diode unit according to claim 2, which is arranged on at least one of a front side and a rear side in a scanning direction of the ink jet head,
wherein the first direction vertically intersects with the scanning direction.

10. An ink jet device comprising:
an ink jet head that discharges ultraviolet curable ink; and
the ultraviolet ray emitting diode unit according to claim 3, which is arranged on at least one of a front side and a rear side in a scanning direction of the ink jet head,
wherein the first direction vertically intersects with the scanning direction.

11. An ink jet device comprising:
an ink jet head that discharges ultraviolet curable ink; and the set of ultraviolet ray emitting diode units according to claim 5, which is arranged on at least one of a front side and a rear side in a scanning direction of the ink jet head,
wherein the first direction vertically intersects with the scanning direction.

12. A three-dimensional modeled object manufacturing device comprising:
the ink jet device according to claim 6, and manufacturing a three-dimensional modeled object by a laminate modeling method.
